(19) United States
(12) Patent Application Publication
(10) Pub. No.: US 2021/0215433 A1
(43) Pub. Date: Jul. 15, 2021

(54) COOLING DEVICE

(71) Applicant: Mitsubishi Electric Corporation, Chiyoda-ku, Tokyo (JP)

(72) Inventors: Hirokazu TAKABAYASHI, Tokyo (JP); Hiroyuki USHIFUSA, Tokyo (JP); Shigetoshi IPPOSHI, Tokyo (JP)

(73) Assignee: Mitsubishi Electric Corporation, Chiyoda-ku, Tokyo (JP)

(21) Appl. No.: 17/056,175

(22) PCT Filed: May 30, 2018
(86) PCT No.: PCT/JP2018/020748

§ 371 Date: Nov. 17, 2020

(51) Int. Cl. F28D 15/02; H01L 23/427

(52) U.S. Cl. CPC F28D 15/0275; H01L 23/427; F28D 2021/0029; F28F 2215/00; F28D 15/0233

(57) ABSTRACT

A cooling device includes (i) a heat receiving block that is a plate-like member to which an exothermic element is attached, and (ii) a cooling member that radiates, to surrounding cooling air, heat transmitted from the exothermic element via the heat receiving block. The cooling device includes (i) at least one header that extends in a Y-axis direction that is a direction in which the cooling air flows, the header being attached to a second main surface, and (ii) branch pipes that are attached to each of the at least one header, the branch pipes extending in a direction away from the second main surface. The branch pipes communicate with the header. A shape of each of the branch pipes in a Y-Z plane is a flat shape, and a longitudinal direction of the flat shape is parallel to the Y-axis direction.

### TECHNICAL FIELD

The present disclosure relates to a cooling device.

### BACKGROUND ART

In order to prevent damage due to heat generated when a semiconductor element is energized, a cooling member is thermally connected to the semiconductor element. The cooling member radiates, to air flowing around the cooling member, heat transferred from the semiconductor element. As a result, heat generation of the semiconductor element is suppressed. An example of the cooling member is a heat sink that includes heat pipes. A heat pipe-type heat sink disclosed in Patent Literature 1 includes: a heat receiving block to which heat is transferred from a semiconductor element, and heat pipes fixed to the heat receiving block. In order to reduce the thickness of the heat receiving block in the horizontal direction, the cross section of each of the heat pipes has an elliptical shape whose major axis extends in the vertical direction.

### CITATION LIST

### Patent Literature

Patent Literature 1: Unexamined Japanese Patent Application Publication No. H08-306836

### SUMMARY OF INVENTION

### Technical Problem

The heat pipes, which are an example of the cooling member, transfer heat to the air flowing around the heat pipes. In other words, the heat pipes are located in the air flow. Accordingly, a separation vortex occurs on the downstream side of each of the heat pipes. In the heat pipe-type heat sink disclosed in Patent Literature 1, the separation vortex occurring when air flows along the minor axis of the cross section of each of the heat pipes is larger than the separation vortex occurring when air flows along the major axis of the cross section of each of the heat pipes. When the separation vortex increases in size, the ventilation resistance increases, and an amount of the air flow decreases. As a result, the cooling efficiency decreases. In other words, when the air flows along the minor axis of the cross section of each of the heat pipe, the cooling efficiency of the heat pipes decreases.

Also, in the heat pipe-type heat sink disclosed in Patent Literature 1, the heat pipes are attached to the heat receiving block independently of one another. Accordingly, heat is not easily transferred between the heat pipes, and a temperature difference occurs between upstream-side heat pipes and downstream-side heat pipes. In other words, a temperature difference occurs in the semiconductor element in accordance with the positions of attachment to the heat receiving block.

The present disclosure is made in view of the above circumstances, and an objective of the present disclosure is to improve cooling efficiency of a cooling device and reduce the temperature difference in an exothermic element cooled by the cooling device.

### Solution to Problem

In order to achieve the aforementioned objective, a cooling device according to the present disclosure includes a heat receiving block and a cooling member. The heat receiving block is a plate-like member, and an exothermic element is attached to a first main surface of the heat receiving block. The cooling member is attached to a second main surface of the heat receiving block, the second main surface being located on a side opposite to the first main surface. The cooling member radiates, to surrounding cooling air, heat transmitted from the exothermic element via the heat receiving block. The cooling member includes a supporting portion and protrusions. The supporting portion is attached to the second main surface. The protrusions are attached to the supporting portion, extend in a direction away from the second main surface, and are spaced in the direction in which the cooling air is to flow. A shape of each of the protrusions in a cross section parallel to the second main surface is a flat shape. The longitudinal direction of the flat shape is parallel to the direction in which the cooling air is to flow.

### Advantageous Effects of Invention

According to the present disclosure, the cooling member includes the supporting portion and the protrusions, the cross-sectional shape of each of the protrusions is a flat shape, and the longitudinal direction of the flat shape is parallel to the direction in which the cooling air flows, thereby enabling improvement of the cooling efficiency of the cooling device and reduction of a temperature difference in the exothermic element cooled by the cooling device.

### BRIEF DESCRIPTION OF DRAWINGS

FIG. 1 is a perspective view of a cooling device according to Embodiment 1 of the present disclosure;

FIG. 2 is a side view of the cooling device according to Embodiment 1;

FIG. 3 is a top view of the cooling device according to Embodiment 1;

FIG. 4 is a front view of the cooling device according to Embodiment 1;

FIG. 5 is a rear view of the cooling device according to Embodiment 1;

FIG. 6 is a cross-sectional view of the cooling device according to the Embodiment 1;

FIG. 7 is a cross-sectional view of an electric power conversion device according to Embodiment 1;

FIG. 8 is a cross-sectional view of the electric power conversion device according to Embodiment 1;

FIG. 9 is a drawing illustrating an example of mounting of the electric power conversion device according to the Embodiment 1 on a railway vehicle;

FIG. 10 is a drawing illustrating air flow around branch pipes each having a circular cross section;

FIG. 11 is a drawing illustrating air flow around branch pipes each having an elliptical cross section;

FIG. 12 is a drawing illustrating air flow around branch pipes according to Embodiment 1;

FIG. 13 is a front view of a cooling device according to Embodiment 2 of the present disclosure;

FIG. 14 is a front view of a first modified example of the cooling device according to Embodiment 2;

FIG. 15 is a front view of a second modified example of the cooling device according to Embodiment 2;

FIG. 16 is a side view of a cooling device according to Embodiment 3 of the present disclosure;

FIG. 17 is a side view of a cooling device according to Embodiment 4 of the present disclosure;

FIG. 18 is a top view of the cooling device according to Embodiment 4;

FIG. 19 is a front view of the cooling device according to Embodiment 4;

FIG. 20 is a side view of a cooling device according to Embodiment 5 of the present disclosure;

FIG. 21 is a top view of the cooling device according to Embodiment 5;

FIG. 22 is a side view of a cooling device according to Embodiment 6 of the present disclosure;

FIG. 23 is a front view of the cooling device according to Embodiment 6; and

FIG. 24 is a perspective view of a cooling device according to Embodiment 7 of the present disclosure.

### DESCRIPTION OF EMBODIMENTS

Cooling devices according to embodiments of the present disclosure are described below in detail with reference to the drawings. Components that are the same or equivalent are assigned the same reference signs throughout the drawings.

### Embodiment 1

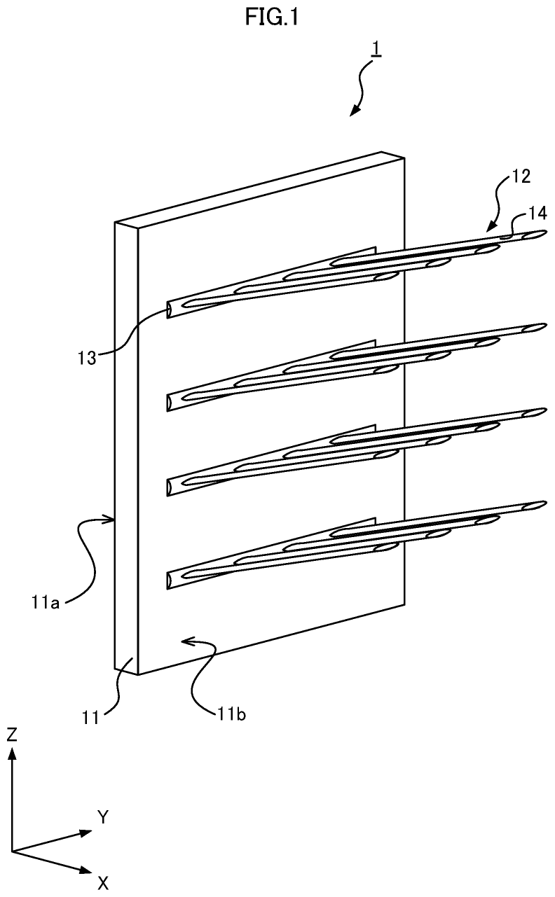

As illustrated in FIG. 1, a cooling device 1 includes (i) a heat receiving block 11 that is a plate-like member to which a later-described exothermic element is attached and (ii) a cooling member 12 that radiates, to surrounding cooling air, heat transmitted from the exothermic element via the heat receiving block 11. In FIG. 1, a Z-axis is taken to be the vertical direction. Also, an X-axis is a direction perpendicular to a first main surface 11a and a second main surface 11b of the heat receiving block 11, and a Y-axis is a direction perpendicular to the X-axis and the Z-axis. The cooling device 1 is used in an environment where a flow direction of cooling air is invariant. In the example of FIG. 1, the cooling air flows in either the positive direction of the Y-axis or the negative direction of the Y-axis.

A semiconductor element is attached, as the exothermic element, to the first main surface 11a of the heat receiving block 11. The cooling member 12 is attached to the second main surface 11b of the heat receiving block 11. The cooling member 12 includes (i) a supporting portion attached to the second main surface 11b, and (ii) protrusions that are attached to the supporting portion, extend in a direction away from the second main surface 11b, and are spaced apart from one another in the direction in which the cooling air flows. The cooling device 1 includes at least one header 13 that extends in the Y-axis direction and is attached to the second main surface 11b, the header 13 serving as the supporting portion. In the example of FIG. 1, the headers 13 are attached to the second main surface 11b with the headers 13 spaced apart from one another in the Z-axis direction. Specifically, each of the headers 13 is attached to a groove formed in the second main surface 11b.

Also, the cooling device 1 includes branch pipes 14 that are attached to each of the at least one header 13 and extend in a direction away from the second main surface 11b, the branch pipes 14 serving as the protrusions. On each of the headers 13, the branch pipes 14 are spaced from one another in the Y-axis direction. The branch pipes 14 spaced from one another in the Y-axis direction communicate with the header 13. In the example of FIG. 1, four headers 13 are attached to the second main surface 11b of the heat receiving block 11. Also, four branch pipes 14 spaced from one another in the Y-axis direction are attached to one header 13 and communicate with this header 13. The header 13 is a supporting portion of the cooling member 12. The branch pipes 14 are the protrusions of the cooling member 12. The header 13 and the branch pipes 14 are heat pipes in which a gas-liquid two-phase refrigerant is sealed.

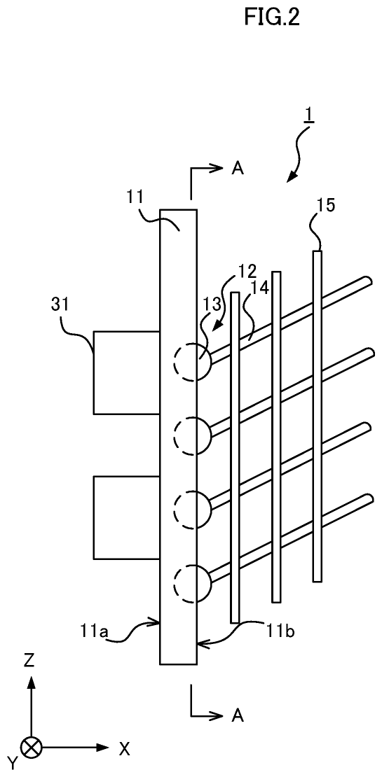

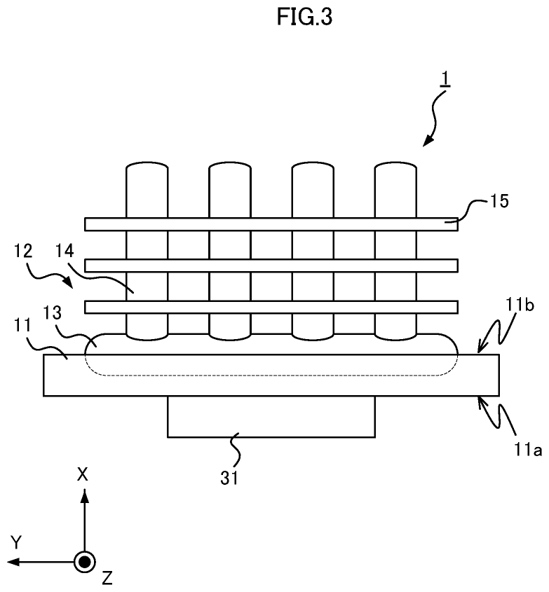

As illustrated in FIGS. 2 and 3, the cooling device 1 further includes fins 15 attached to the branch pipes 14. In FIG. 1, the fins 15 are omitted for easy understanding of the drawing. The inclusion of the fins 15 in the cooling device 1 enables an increase in the cooling efficiency of the cooling device 1.

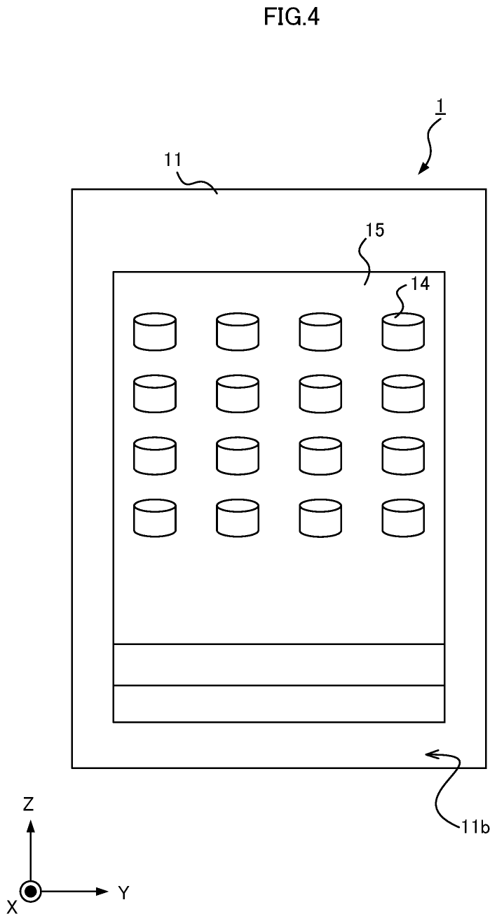

The shape of each of the branch pipes 14 on the Y-Z plane is a flat shape, and the longitudinal direction of the flat shape is parallel to the Y-axis direction. The term, “flat shape”, means a shape obtained by deforming a part of a circle such that the part of the circle has a narrower width than that of the original circle, and examples of such a flat shape include an elliptical shape, a streamline shape, an oval shape and the like. Furthermore, the term, “oval shape”, means a shape obtained by connecting, by straight lines, the outer edges of circles having the same diameter. As illustrated in FIG. 4, the shape of the branch pipe 14 in the Y-Z plane is an elliptical shape. The major axis of the elliptical shape is parallel to the Y-axis. The major axis of the cross section of the branch pipe 14 on the Y-Z plane is arranged parallel to the Y-axis that is the direction in which the cooling air flows, thereby, as described later, enabling (i) reduction of a separation vortex occurring on the downstream side of the cooling air relative to the branch pipe 14 and (ii) the improvement of the cooling efficiency.

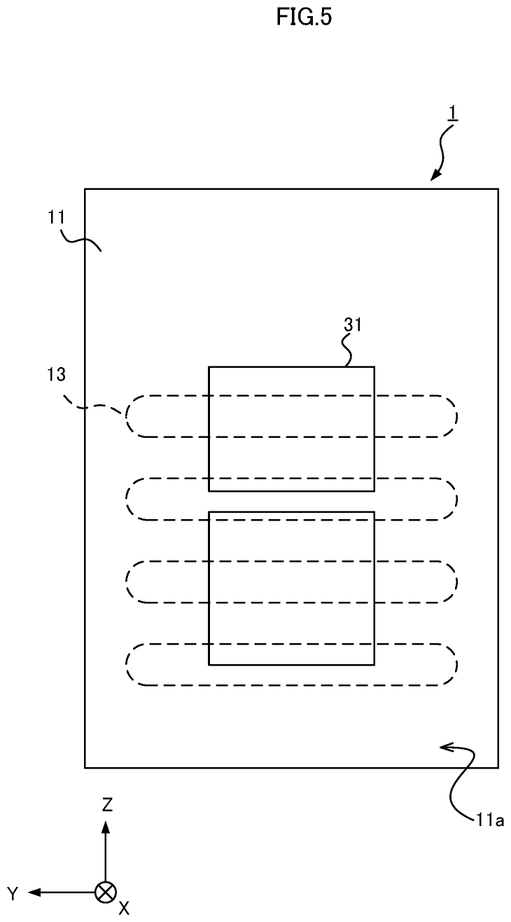

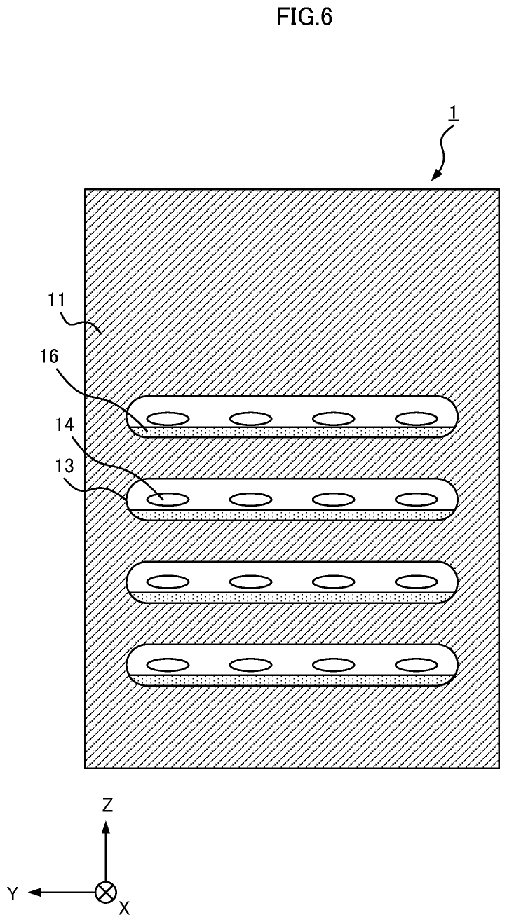

As illustrated in FIGS. 2 and 5, an exothermic element 31 is attached to the first main surface 11a that is located on a side opposite to the header 13 of the heat receiving block 11. FIG. 6 is a cross-sectional view taken along line A-A in FIG. 2. As illustrated in FIG. 6, the inside of the header 13 is filled with refrigerant 16 that is in a gas-liquid two-phase state. When the temperature of the exothermic element 31 rises, heat is transferred, via the heat receiving block 11 and the header 13, from the exothermic element 31 to the refrigerant 16. As a result, the refrigerant 16 that is in a liquid state changes to a gas. The gaseous refrigerant 16 moves from the header 13 to the branch pipes 14 and further moves inside the branch pipes 14 to the tips of the branch pipes 14. While moving inside the branch pipes 14 to the tips of the branch pipes 14, the refrigerant 16 transfers heat to the branch pipes 14. Additionally, the branch pipes 14 radiate heat to the surrounding cooling air via the fins 15. The transfer of the heat to the branch pipes 14 by the refrigerant 16 causes a decrease in the temperature of the refrigerant 16 and thus making the refrigerant 16 to change to a liquid. The liquified refrigerant 16 runs along the inner walls of the branch pipes 14 and returns to the header 13.

When the temperature of a portion of the refrigerant 16 rises inside the header 13, convection of the refrigerant 16 occurs in the header 13. The occurrence of the convection of the refrigerant 16 suppresses movement of the gaseous refrigerant 16 toward only a part of the branch pipes 14, thereby enabling reduction of a temperature difference between a branch pipe 14 located on the upstream side of the cooling air and a branch pipe 14 located on the downstream side of the cooling air. In other words, since multiple branch pipes 14 are attached to the header 13, the temperature difference in the exothermic element 31 can be reduced.

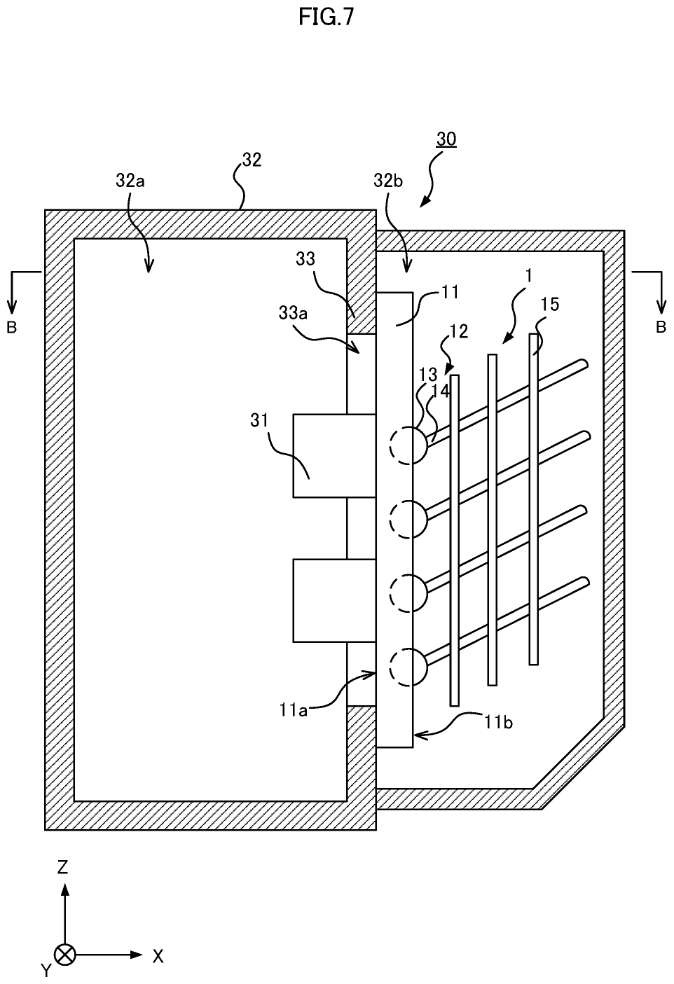

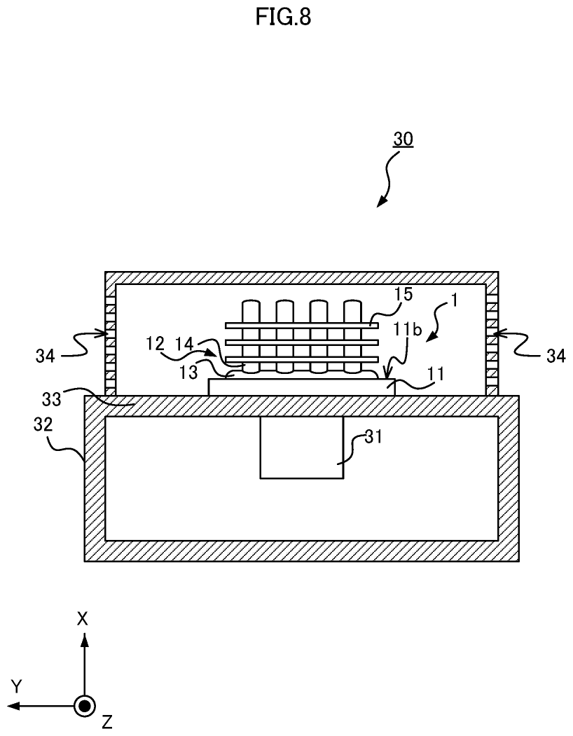

As illustrated in FIGS. 7 and 8, the cooling device 1 is mounted on an electric power conversion device 30. Also, FIG. 8 is a cross-sectional view taken along line B-B in FIG. 7. The electric power conversion device 30 includes (i) a housing 32, (ii) the exothermic element 31 stored in the housing 32, and (iii) the cooling device 1 that cools the exothermic element 31. The housing 32 includes a partition 33 that divides the inside of the housing 32 into a closed portion 32a and an open portion 32b. The exothermic element 31 is stored in the closed portion 32a. The cooling device 1 is stored in the open portion 32b. The partition 33 has an opening 33a. The opening 33a is covered by the first main surface 11a of the heat receiving block 11 included in the cooling device 1. The exothermic element 31 is attached to the first main surface 11a that covers the opening 33a. The opening 33a is covered by the first main surface 11a, thereby suppressing flows of external air, moisture, dust, and the like into the closed portion 32a.

Also, in the housing 32 surrounding the open portion 32b, air intake/exhaust ports 34 are formed in two surfaces perpendicular to the Y-axis direction. The cooling air flowing in from one of the air intake/exhaust ports 34 passes between the branch pipes 14 along the fins 15 and is discharged from the intake/exhaust port 34 formed in the other of two surfaces. The cooling air flows between the branch pipes 14 in the Y-axis direction, thereby cooling the exothermic element 31.

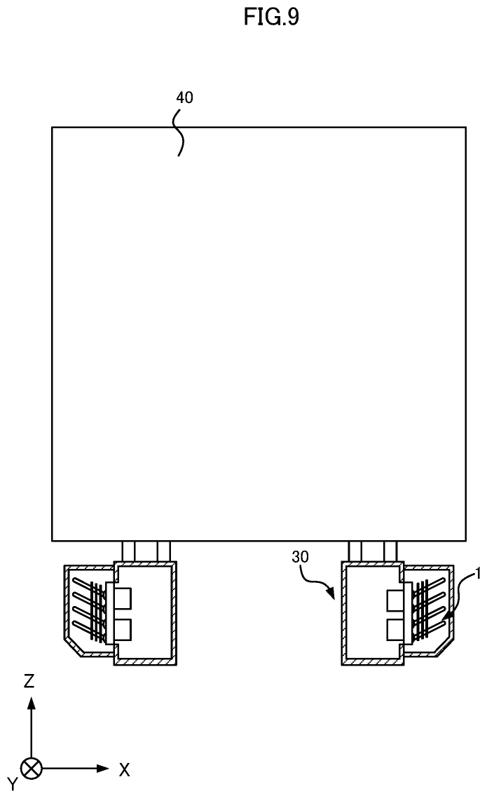

As illustrated in FIG. 9, the electric power conversion device 30 including the cooling device 1 is attached under a floor of a railway vehicle 40. In FIG. 9, the Y-axis direction is a traveling direction of the railway vehicle. The exothermic element 31 is cooled by taking, into the open portion 32b of the power conversion device 30, a traveling wind flowing along the traveling direction.

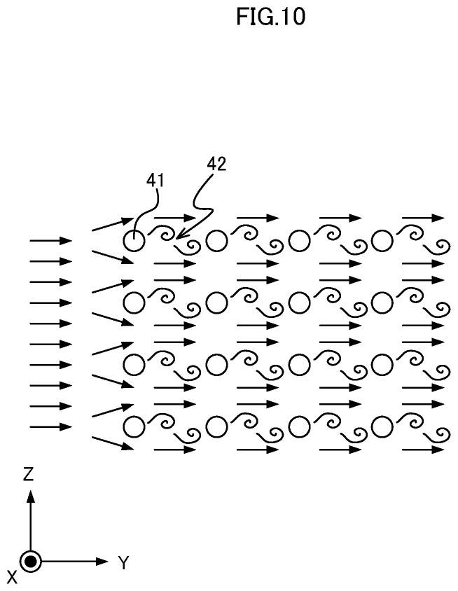

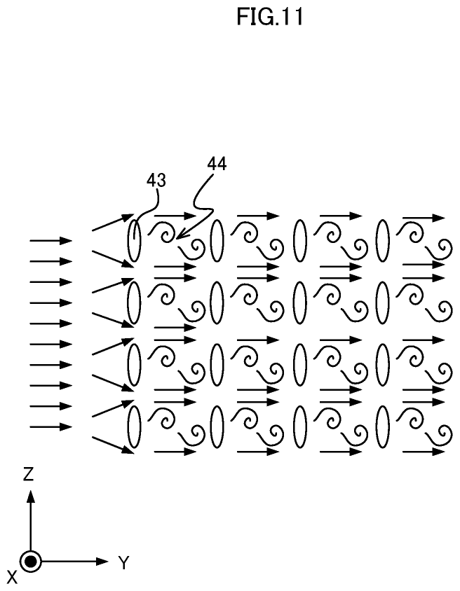

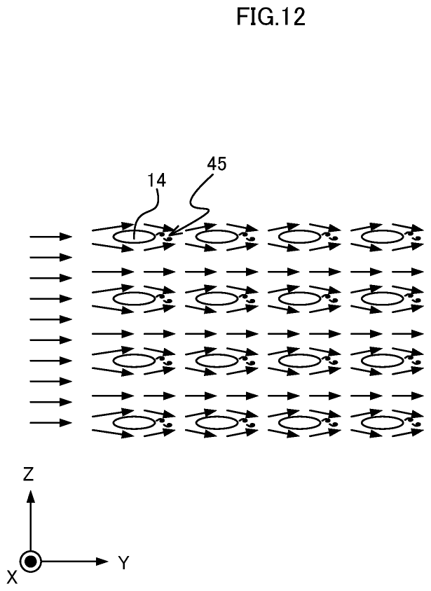

The separation vortex occurring on the downstream side of the cooling air relative to the branch pipes 14 is described with reference to FIGS. 10 to 12. As described above, the Y-axis direction is the traveling direction of the railway vehicle. Accordingly, the cooling air flows parallel to the Y-axis direction. Whether in the case of cooling air flow in the positive direction of the Y-axis or in the negative direction of the Y-axis, there is no difference in how the separation vortex occurs. Thus, an example is described here in which the cooling air flows in the positive direction of the Y-axis. FIG. 10 is a drawing illustrating air flow around branch pipes each having a circular cross-sectional shape. FIG. 11 is a drawing illustrating an air flow around branch pipes each having an elliptical cross-sectional shape whose major axis extends in the vertical direction. In the example of FIG. 11, the major axis of the cross-sectional shape of each of the branch pipes is perpendicular to the direction in which the cooling air flows. FIG. 12 is a drawing illustrating an air flow around branch pipes 14 according to Embodiment 1. As indicated by arrows in FIGS. 10 to 12, the cooling air flows in the positive direction of the Y-axis. Branch pipes 41 and 43 are assumed to have the same cross-sectional areas in the Y-Z plane as those of the branch pipes 14. Separation vortices 42 occur on the downstream side of the cooling air relative to each of the branch pipes 41. Also, a separation vortices 44 occur on the downstream side of the cooling air relative to the branch pipes 43. Also, separation vortices 45 occur on the downstream side of the cooling air relative to each of the branch pipes 14. The shape of each of the branch pipes 14 in the Y-Z plane is an elliptical shape, and the major axis is parallel to the Y-axis direction. Accordingly, since the width of the branch pipe 14 in the Z-axis direction is smaller than that of the branch pipe 41 having a circular cross-sectional shape, the sizes of the separation vortices 45 are smaller than those of the separation vortices 42. Since the width of the branch pipe 14 in the Z-axis direction is smaller than that of each of the branch pipes 43 having a cross-sectional shape whose major axis is parallel to the Z-axis direction, the sizes of the separation vortices 45 are smaller than those of the separation vortices 44. In order to make the separation vortices 45 sufficiently small, the major axis of the branch pipe 14 on the Y-Z plane is preferably four times or more the minor axis of the branch pipe 14. Since the separation vortices 45 are smaller than the separation vortices 42 and 44, ventilation resistance is reduced, and the air flow rate is increased. As a result, the cooling efficiency of the cooling device 1 is improved.

As described above, according to the cooling device 1 according to Embodiment 1, the cross-sectional shape of each of the branch pipes 14 in the Y-Z plane is a flat shape, and the longitudinal direction of the flat shape is parallel to the direction in which the cooling air flows, thereby enabling the improvement of the cooling efficiency of the cooling device 1 and the reduction of the temperature difference in the exothermic element 31.

### Embodiment 2

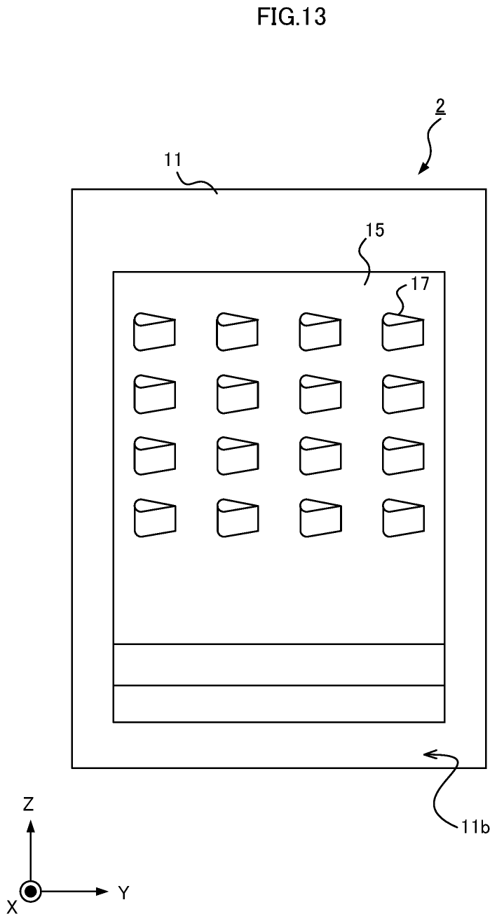

The cross-sectional shapes of the branch pipes are not limited to the elliptical shapes. As illustrated in FIG. 13, a cooling device 2 according to Embodiment 2 includes branch pipes 17 instead of the branch pipes 14. The structure of the cooling device 2, other than the branch pipes 17, is the same as that of the cooling device 1. Also, the arrangement positions at which the branch pipes 17 are arranged are the same as those at which the branch pipes 14 are arranged in Embodiment 1. The shape of each of the branch pipes 17 in the Y-Z plane is a streamline shape. One end of the streamline shape is rounder than the other end of the streamline shape. The rounded end is referred to as a front edge, and the other end that is sharper than the front edge is referred to as a rear edge. In the cooling device 2, the cooling air flows in the positive direction of the Y-axis. Each of the branch pipes 17 is attached to the header 13 such that, in the direction in which the cooling air flows, the front edge is positioned nearer to the upstream side than the rear edge. In other words, the front edge is located nearer to the negative direction side of the Y-axis than the rear edge. The streamline-shaped cross section of the branch pipe 17 on the Y-Z plane enables the reduction of the sizes of the separation vortices as in Embodiment 1.

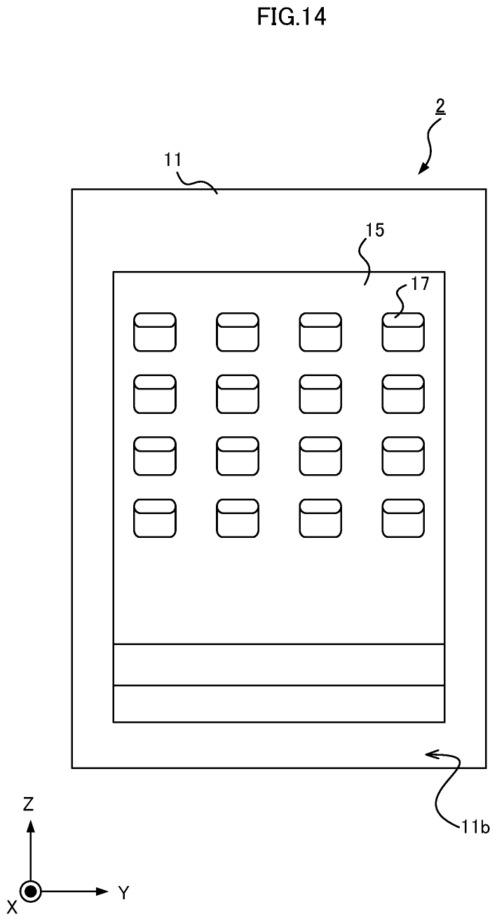

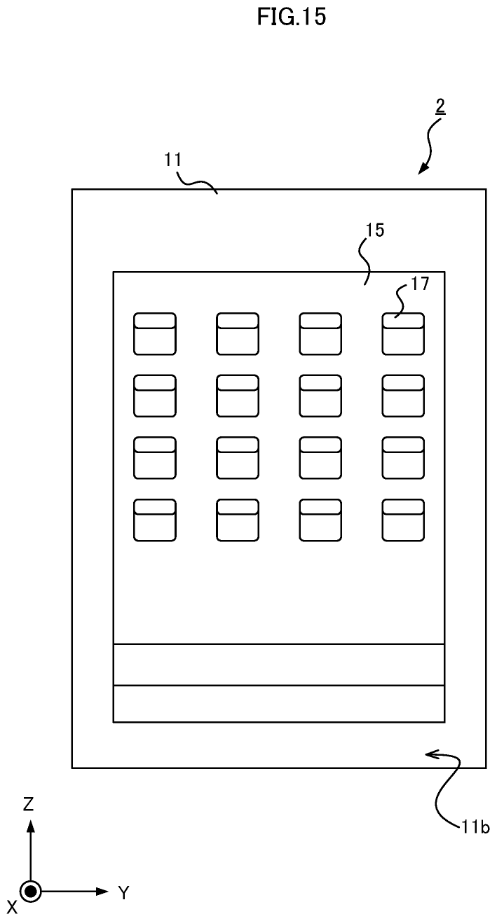

The cross-sectional shape of each of the branch pipes 17 is not limited to the elliptical shape or the streamline shape and may be an oval shape as illustrated in FIG. 14. The branch pipes 17 are arranged such that the longitudinal direction of the oval shape is parallel to the Y-axis. Also, the cross-sectional shape of each of the branch pipes 17 may be a rectangular shape with rounded corners as illustrated in FIG. 15. The branch pipes 17 are arranged such that the longitudinal direction of the rectangular shape is parallel to the Y-axis. In any such shape, the sizes of the separation vortices can be reduced as in Embodiment 1.

As described above, according to the cooling device 2 according to Embodiment 2, the cross-sectional shape of each of the branch pipes 17 in the Y-Z plane is the streamline shape, and the longitudinal direction of the streamline shape is parallel to the direction in which the cooling air flows, thereby enabling the improvement of the cooling efficiency of the cooling device 2. Also, the cross-sectional shape of the branch pipe 17 on the Y-Z plane is set to be the oval shape or the rectangular shape with the rounded corners, and the longitudinal directions of the oval shape and the rectangular shape are parallel to the direction in which the cooling air flows, thereby enabling the improvement of the cooling efficiency of the cooling device 2.

### Embodiment 3

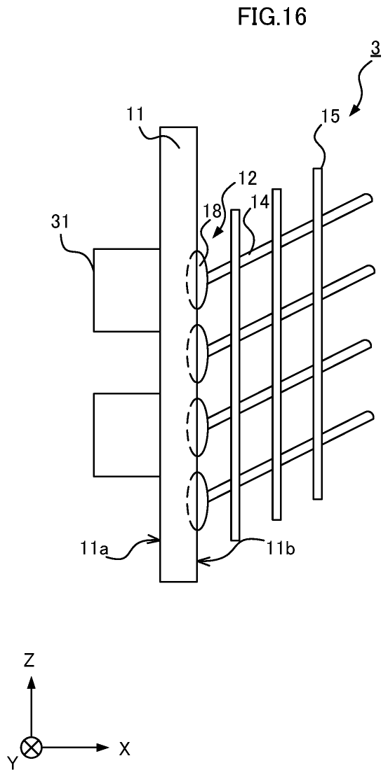

In Embodiments 1 and 2, the cross section of each of the headers 13 in the X-Z plane has a circular shape. However, the cross-sectional shape of the header is not limited to the circular shape and may be an elliptical shape, a streamline shape, an oval shape or the like. As illustrated in FIG. 16, a cooling device 3 according to Embodiment 3 includes headers 18 instead of the headers 13. The structure of the cooling device 3, other than the headers 18, is the same as that of the cooling device 1. Similarly to Embodiment 1, the headers 18 extend in the Y-axis direction. The headers 18 are attached to the second main surface 11b with the headers 18 spaced apart from one another in the Z-axis direction. The cross section of each of the headers 18 in the X-Z plane has an elliptical shape. The major axis of the elliptical shape is perpendicular to the direction from the first main surface 11a to the second main surface 11b, that is, the X-axis direction. In other words, the major axis of the elliptical shape is parallel to the Z-axis direction.

Each of the headers 18 has the same cross-sectional area in the X-Z plane as that of each of the headers 13. Since a surface area of each of the headers 18 is larger than the surface area of each of the headers 13, the efficiency of heat transfer from the heat receiving block 11 to the refrigerant 16 is improved. As a result, the cooling efficiency of the cooling device 3 is improved.

As described above, according to the cooling device 3 according to Embodiment 3, the cross-sectional shape of each of the headers 18 on the X-Z plane is the elliptical shape, and the major axis of the elliptical shape is parallel to the Z-axis direction, thereby enabling the improvement of the cooling efficiency of the cooling device 3.

### Embodiment 4

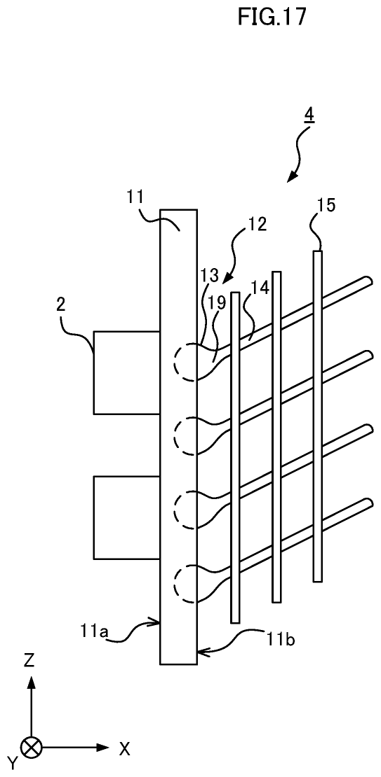

In Embodiment 1, the headers 13 and the branch pipes 14 are formed separately, and the branch pipes 14 are attached to the headers 13. However, the headers 13 and the branch pipes 14 may be formed integrally with one another. As illustrated in FIG. 17, the cooling member 12 included in a cooling device 4 according to Embodiment 4 includes a header 13, branch pipes 14, and connecting pipes 19 that connect the header 13 and the branch pipes 14. The headers 13, the branch pipes 14, and each of the connecting pipes 19 can be formed by processing a single pipe having a circular cross section.

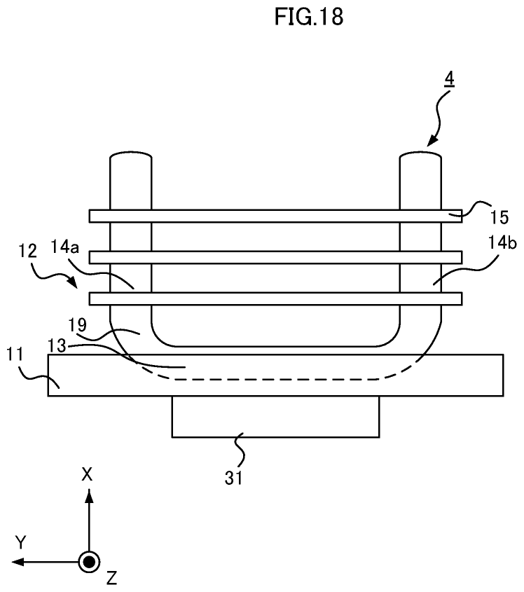

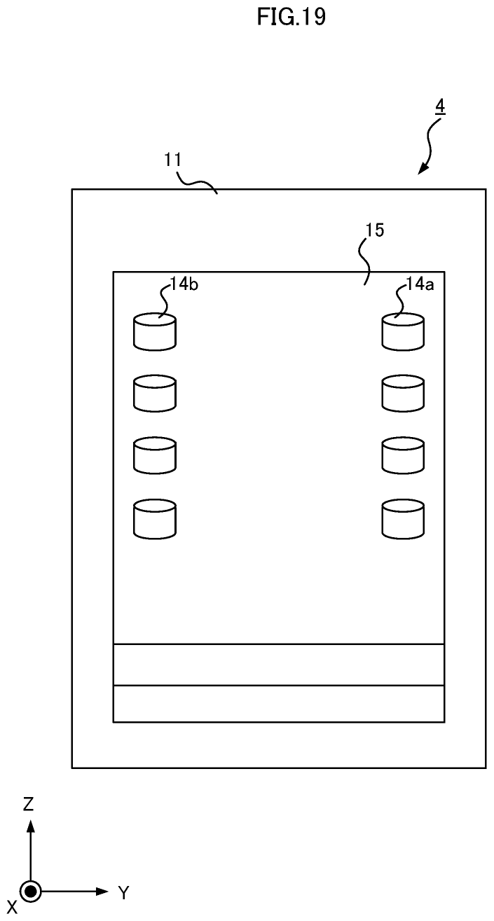

As illustrated in FIGS. 18 and 19, the cooling device 4 includes a branch pipe 14a (first branch pipe) and a branch pipe 14b (second branch pipe) communicating with the same header 13. The branch pipe 14a communicates with one end of the header 13 via a connecting pipe 19, and the branch pipe 14b communicates with the other end of the header 13 via a connecting pipe 19.

The cross-sectional shape of the header 13 in the X-Z plane is a circular shape. Also, the cross-sectional shape of each of the branch pipes 14a and 14b in the Y-Z plane is an elliptical shape. Accordingly, the cross-sectional shape of each of the connecting pipes 19 continuously changes from the elliptical shape to the circular shape. The header 13, the branch pipes 14, and the connecting pipe 19 can be formed by processing the single pipe such that the vertical direction width of the single pipe becomes narrow toward ends of the single pipe.

As described above, according to the cooling device 4 according to Embodiment 4, manufacturing processing can be simplified by integrally forming the header 13, the branch pipes 14, and the connecting pipes 19.

### Embodiment 5

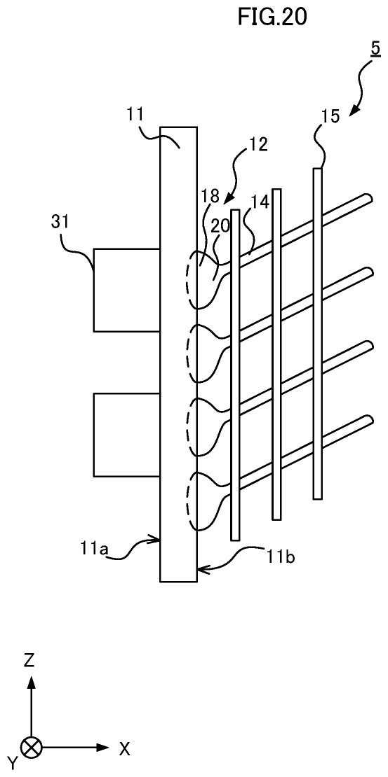

In Embodiment 3, the headers 18 and the branch pipes 14 are formed separately, and the branch pipes 14 are attached to the headers 18. However, the headers 18 and the branch pipes 14 may be formed integrally with one another. As illustrated in FIG. 20, the cooling member 12 included in a cooling device 5 according to Embodiment 5 includes a header 18, branch pipes 14, and connecting pipes 20 that connects the header 18 and the branch pipes 14. The header 18, the branch pipes 14, and the connecting pipe 20 can be formed by processing a single pipe having a circular cross section.

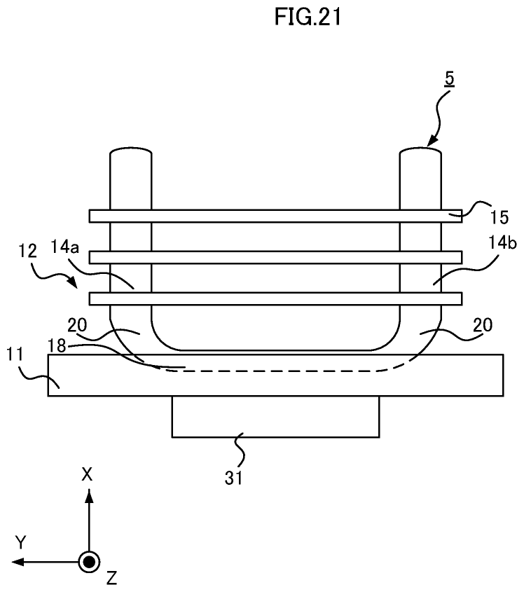

As illustrated in FIG. 21, the cooling device 5 includes the branch pipe 14a (first branch pipe) and the branch pipe 14b (second branch pipe) communicating with the same header 18. The branch pipe 14a communicates with one end of the header 18 via the connecting pipe 20, and the branch pipe 14b communicates with the other end of the header 18 via the connecting pipe 20.

The cross-sectional shape of the header 18 in the X-Z plane is an elliptical shape whose major axis is parallel to the Z-axis. Also, the cross-sectional shape of each of the branch pipes 14a and 14b in the Y-Z plane is an elliptical shape whose major axis is parallel to the Y-axis. Accordingly, the cross-sectional shape of the connecting pipe 20 continuously changes from (i) the elliptical shape whose major axis is parallel to the Y-axis to (ii) the elliptical shape whose major axis is parallel to the Z-axis. The header 18, the branch pipes 14 and the connecting pipe 20 can be formed by processing a single pipe such that (i) the vertically directional width of the single pipe becomes narrow toward ends of the single pipe and (ii) the horizontally directional width of the single pipe becomes narrow toward the center of the single pipe.

As described above, according to the cooling device 5 according to Embodiment 5, the manufacturing process can be simplified by integrally forming the header 18, the branch pipes 14, and the connecting pipe 20.

### Embodiment 6

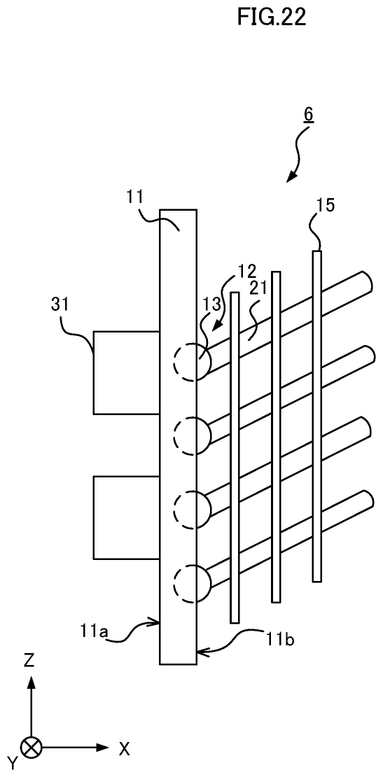

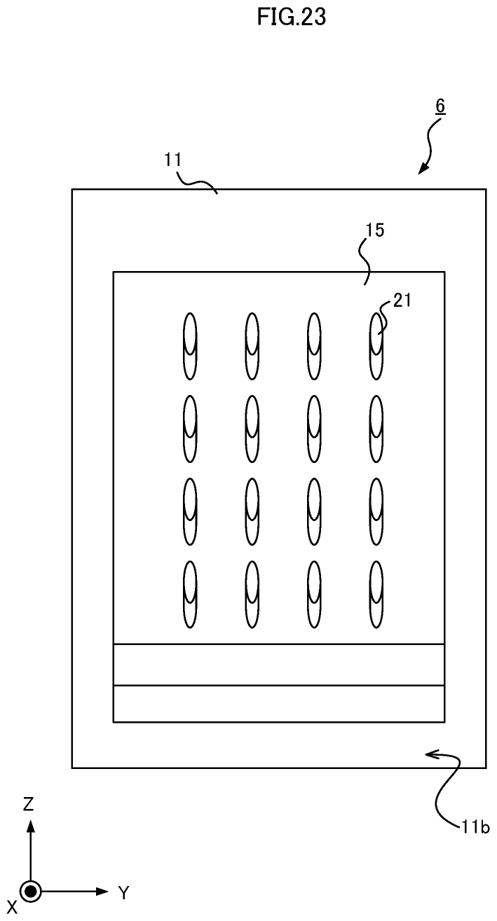

In the above-described embodiments, the cooling air flows in the Y-axis direction, that is, in the horizontal direction. However, the cooling air may flow in the Z-axis direction, that is, the vertical direction. When the exothermic element 31 is cooled by natural air cooling, the cooling air flows in the Z-axis direction. As illustrated in FIGS. 22 and 23, a cooling device 6 according to Embodiment 6 includes branch pipes 21 instead of the branch pipes 14. The structure of the cooling device 6, other than the branch pipes 21, is the same as that of the cooling device 1. Also, positions at which the branch pipes 21 are arranged are the same as the positions at which the branch pipes 14 are arranged in Embodiment 1. The shape of each of the branch pipes 21 on the Y-Z plane is an elliptical shape whose major axis is parallel to the Z-axis direction. In the cooling device 6, the cooling air flows in the positive direction of the Z-axis. Since the major axis of the branch pipe 21 on the Y-Z plane is parallel to the direction in which the cooling air flows, the cooling efficiency of the cooling device 6 can be improved. Also, since the branch pipes 21 are attached to the header 13 similarly to Embodiment 1, the temperature difference in the exothermic body 31 can be reduced.

As described above, according to the cooling device 6 according to Embodiment 6, the cross-sectional shape of each of the branch pipes 21 in the Y-Z plane is a flat shape, and the longitudinal direction of the flat shape is parallel to the direction in which the cooling air flows, thereby enabling the improvement of the cooling efficiency of the cooling device 6 and reduction of the temperature difference in the exothermic element 31.

### Embodiment 7

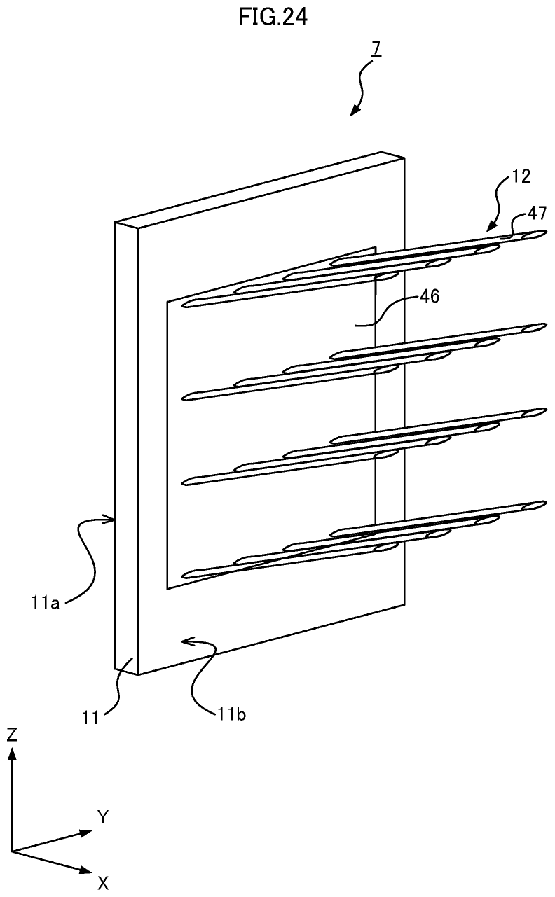

In the above-described embodiments, the cooling member 12 includes a heat pipe. The cooling member 12 may include a metal member. As illustrated in FIG. 24, the cooling member 12 includes (i) a metal plate 46 attached to the heat receiving block 11 and (ii) rod-like metal rods 47 attached to the metal plate 46. The metal rods 47 are attached to the metal plate 46 at intervals in the direction in which the cooling air flows. Additionally, the metal rods 47 are attached to the metal plate 46 with the metal rods 47 spaced apart from one another in the Z-axis direction. By providing the metal plate 46 and the metal rods 47 described above, the cooling member 12 has a hedgehog-like pin array shape. The shape of each of the metal rods 47 in the Y-Z plane is an elliptical shape, and the major axis of the elliptical shape is parallel to the Y-axis direction. The cooling efficiency of the cooling device 7 is improved by providing the metal rods 47 each of which has a cross-sectional shape that is the elliptical shape whose major axis is parallel to the direction in which the cooling air flows. Also, since the metal rods 47 are attached to the metal plate 46, a temperature difference does not occur between the metal rods 47 located on the upstream side of the cooling air and the metal rods 47 located on the downstream side of the cooling air.

As described above, according to the cooling device 7 according to Embodiment 7, the cross-sectional shape of each of the metal rods 47 in the Y-Z plane is a flat shape, and the longitudinal direction of the flat shape is parallel to the direction in which the cooling air flows, thereby enabling the improvement of the cooling efficiency of the cooling device 7 and the reduction of the temperature difference in the exothermic element 31.

Two or more embodiments among the above-described embodiments may be freely combined with one another. For example, the headers 13 and the branch pipes 17 may be formed integrally, or the headers 13 and the branch pipes 21 may be formed integrally. Also, the branch pipes 17 may be attached to the headers 18.

The present disclosure is not limited to the above-described examples. The branch pipes 14, 17, 21, 41, and 43 each have a freely-selected shape having a longitudinal direction and a lateral direction, and are arranged such that the longitudinal direction is along the direction in which the cooling air flows. In the above-described embodiments, the streamline shape that has a line of symmetry in the longitudinal direction is described. However, airfoil branch pipes each having a streamline shape that lacks a line of symmetry in the longitudinal direction may be provided. Also, the number of the headers 13 and 18 and the number of branch pipes 14, 17, and 21 are freely selected. Also, the cooling member 12 is not limited to a heat pipe, and may be a metal member that has a hedgehog-like pin array shape.

A switching element that is formed of a wide bandgap semiconductor may be attached, as the exothermic element 31, to the heat receiving block 11. The wide bandgap semiconductor includes, for example, silicon carbide, gallium nitride-based material, or diamond. The switching element formed by the wide band gap semiconductor is miniaturized relative to a switching element using silicon, and thus generates a large amount of heat per unit area. As described above, in the cooling devices 1 to 7 according to the present embodiments, the cooling efficiency can be improved, so that the switching element formed by the wide band gap semiconductor that generates a large amount of heat can be cooled.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1, 2, 3, 4, 5, 6, 7 Cooling device
11 Heat receiving block
11a First main surface
11b Second main surface
12 Cooling member
13, 18 Header
14, 14a, 14b, 17, 21, 41, 43 Branch pipe
15 Fin
16 Refrigerant
19, 20 Connecting pipe
30 Electric power conversion device
31 Exothermic element
32 Housing
32a Closed portion
32b Open portion
33 Partition
33a Opening
34 Air intake/exhaust port
40 Railway vehicle
42, 44, 45 Separation vortex
46 Metal plate
47 Metal rod

1. A cooling device comprising:
a heat receiving block including
a first main surface to which an exothermic element is attached, and
a second main surface located on a side opposite to the first main surface,
the heat receiving block being a plate-like member; and
a cooling member to radiate, to surrounding cooling air, heat transmitted from the exothermic element via the heat receiving block, the cooling member being attached to the second main surface of the heat receiving block, wherein
the cooling member comprises:
a supporting portion attached to the second main surface, and
protrusions attached to the supporting portion, the protrusions extending in a direction away from the second main surface, the protrusions being spaced apart in a direction in which the cooling air is to flow,
a shape of each of the protrusions on a cross section parallel to the second main surface is a flat shape,
a longitudinal direction of the flat shape is parallel to the direction in which the cooling air is to flow,
the supporting portion is at least one header extending parallel to the second main surface,
the protrusions are branch pipes attached to the at least one header such that the branch pipes are spaced apart in the direction in which the cooling air is to flow, the branch pipes extending in the direction away from the second main surface, the branch pipes communicating with the header,
the cooling member further comprises a refrigerant that is to be sealed inside the at least one header and the branch pipes, the refrigerant being in a gas-liquid two-phase state,
a shape of each of the branch pipes in the cross section parallel to the second main surface is a flat shape, and
a longitudinal direction of the flat shape of the branch pipes is parallel to the direction in which the cooling air is to flow.

2. The cooling device according to claim 1, further comprising:
fins attached to the branch pipes.

3. The cooling device according to claim 1, wherein
a plurality of the headers is attached to the second main surface such that the headers are spaced apart in a direction perpendicular to the direction in which the cooling air is to flow, and
the branch pipes are attached to the headers.

4-13. (canceled)

14. The cooling device according to claim 2, wherein
a plurality of the headers is attached to the second main surface such that the headers are spaced apart in a direction perpendicular to the direction in which the cooling air is to flow, and
the branch pipes are attached to the headers.

15. The cooling device according to claim 1, wherein
the shape of each of the branch pipes in the cross section parallel to the second main surface is a shape obtained by connecting, by straight lines, outer edges of circles having the same diameter, and
a long axis of the shape obtained by connecting, by the straight lines, the outer edges of the circles having the same diameter is parallel to the direction in which the cooling air is to flow.

16. The cooling device according to claim 2, wherein
the shape of each of the branch pipes in the cross section parallel to the second main surface is a shape obtained by connecting, by straight lines, outer edges of circles having the same diameter, and
a long axis of the shape obtained by connecting, by the straight lines, the outer edges of the circles having the same diameter is parallel to the direction in which the cooling air is to flow.

17. The cooling device according to claim 3, wherein
the shape of each of the branch pipes in the cross section parallel to the second main surface is a shape obtained by connecting, by straight lines, outer edges of circles having the same diameter, and
a long axis of the shape obtained by connecting, by the straight lines, the outer edges of the circles having the same diameter is parallel to the direction in which the cooling air is to flow.

18. The cooling device according to claim 1, wherein
the shape of each of the branch pipes in the cross section parallel to the second main surface is an elliptical shape, and
a major axis of the elliptical shape is parallel to the direction in which the cooling air is to flow.

19. The cooling device according to claim 2, wherein
the shape of each of the branch pipes in the cross section parallel to the second main surface is an elliptical shape, and
a major axis of the elliptical shape is parallel to the direction in which the cooling air is to flow.

20. The cooling device according to claim 3, wherein
the shape of each of the branch pipes in the cross section parallel to the second main surface is an elliptical shape, and
a major axis of the elliptical shape is parallel to the direction in which the cooling air is to flow.

21. The cooling device according to claim 1, wherein
the shape of each of the branch pipes in the cross section parallel to the second main surface is a streamline shape, and
a longitudinal axis of the streamline shape is parallel to the direction in which the cooling air is to flow.

22. The cooling device according to claim 2, wherein
the shape of each of the branch pipes in the cross section parallel to the second main surface is a streamline shape, and
a longitudinal axis of the streamline shape is parallel to the direction in which the cooling air is to flow.

23. The cooling device according to claim 3, wherein
the shape of each of the branch pipes in the cross section parallel to the second main surface is a streamline shape, and
a longitudinal axis of the streamline shape is parallel to the direction in which the cooling air is to flow.

24. The cooling device according to claim 21, wherein
the cooling air flows in a single direction, and
a front edge of the streamline shape is located nearer than a rear edge of the streamline shape to an upstream side in the direction in which the cooling air is to flow.

25. The cooling device according to claim 1, wherein
a shape of the header in a cross section perpendicular to a direction in which the header extends is a circular shape.

26. The cooling device according to claim 1, wherein
a shape of the header in a cross section perpendicular to the direction in which the header extends is an elliptical shape, and
a major axis of the elliptical shape is perpendicular to a direction from the first main surface to the second main surface.

27. The cooling device according to claim 1, wherein
the cooling device comprises a first branch pipe and a second branch pipe as two of the branch pipes communicating with the same header,
the first branch pipe communicates with one end of the header,
the second branch pipe communicates with another end of the header, and
the header, the first branch pipe, and the second branch pipe are integrally connected with one another.

28. The cooling device according to claim 1, wherein
the at least one header extends in the direction in which the cooling air is to flow.

29. The cooling device according to claim 1, wherein
the direction in which the cooling air is to flow is a horizontal direction.

30. The cooling device according to claim 1, wherein
the direction in which the cooling air is to flow is a vertical direction.
